(19) United States
(12) Patent Application Publication
(10) Pub. No.: US 2026/0343931 A1
(43) Pub. Date: Oct. 29, 2026

(54) SEMICONDUCTOR DEVICE AND METHOD FOR MANUFACTURING SEMICONDUCTOR DEVICE

(71) Applicant: Fujitsu Limited, Kawasaki-shi (JP)

(72) Inventors: Kenji HOMMA, Atsugi (JP); Toshihiro OHKI, Hadano (JP); Yoichi KAMADA, Machida (JP)

(73) Assignee: Fujitsu Limited, Kawasaki-shi (JP)

(21) Appl. No.: 19/651,075

(22) Filed: Apr. 17, 2026

(30) Foreign Application Priority Data
Apr. 24, 2025 (JP) 2025-072242

(51) Int. Cl. H10D 30/47; H10D 30/01; H10D 62/85; H10W 74/01; H10W 74/10; H10W 74/43

(52) U.S. Cl. CPC H10D 30/475; H10D 30/015; H10D 62/8503; H10W 74/01; H10W 74/137; H10W 74/43

(57) ABSTRACT

A semiconductor device includes a semiconductor layer, an amorphous insulating layer, provided on the semiconductor layer, including silicon and nitrogen, and having an opening reaching the semiconductor layer, and a gate electrode having a portion inside the opening and in Schottky contact with the semiconductor layer. The insulating layer includes a first region having a density that becomes higher as a distance from the semiconductor layer increases.

### CROSS-REFERENCE TO RELATED APPLICATIONS

This application is based upon and claims the benefit of priority of Japanese Patent Application No. 2025-072242, filed on Apr. 24, 2025, the entire contents of which are incorporated herein by reference.

### FIELD

Certain aspects of the embodiments discussed herein are related to semiconductor devices and methods for manufacturing semiconductor devices.

### BACKGROUND

A known semiconductor device includes a high electron mobility transistor (HEMT) having a gate electrode in Schottky contact with a semiconductor layer.

Examples of the related art include Japanese Laid-Open Patent Publication No. 2014-199864, Japanese Laid-Open Patent Publication No. 2019-145605, U.S. Patent Application Publication No. 2014/0319583, and U.S. Patent Application Publication No. 2013/0146944, for example.

In recent years, there are increased demands to reduce a leakage current between the gate electrode and the semiconductor layer.

### SUMMARY

It is an object in one aspect of the embodiments of the present disclosure to provide a semiconductor device and a method for manufacturing the semiconductor device capable of reducing a leakage current.

According to one aspect of the embodiments of the present disclosure, a semiconductor device includes a semiconductor layer; an amorphous insulating layer, provided on the semiconductor layer, including silicon and nitrogen, and having an opening reaching the semiconductor layer; and a gate electrode having a portion inside the opening and in Schottky contact with the semiconductor layer, wherein the insulating layer includes a first region having a density that becomes higher as a distance from the semiconductor layer increases.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a cross sectional view illustrating a semiconductor device according to a first embodiment;

FIG. 2 is a cross sectional view illustrating a method for manufacturing the semiconductor device according to the first embodiment;

FIG. 3 is a cross sectional view illustrating the method for manufacturing the semiconductor device according to the first embodiment;

FIG. 4 is a cross sectional view illustrating the method for manufacturing the semiconductor device according to the first embodiment;

FIG. 5 is a cross sectional view illustrating the method for manufacturing the semiconductor device according to the first embodiment;

FIG. 6 is a cross sectional view illustrating the method for manufacturing the semiconductor device according to the first embodiment;

FIG. 7 is a cross sectional view illustrating the method for manufacturing the semiconductor device according to the first embodiment;

FIG. 8 is a cross sectional view illustrating the method for manufacturing the semiconductor device according to the first embodiment;

FIG. 9 is a cross sectional view illustrating a semiconductor device according to a reference example;

FIG. 10 is a cross sectional view illustrating an insulating layer and a gate electrode of the reference example;

FIG. 11 is a diagram illustrating band structures in a portion where a gate electrode is in Schottky contact with a semiconductor layer and a portion where an alloy layer is in Schottky contact with the semiconductor layer;

FIG. 12 is a diagram illustrating results of measurement using an X-ray reflectivity method;

FIG. 13 is a diagram illustrating a discrete package according to a second embodiment;

FIG. 14 is a circuit diagram illustrating a PFC circuit according to a third embodiment;

FIG. 15 is a circuit diagram illustrating a power supply device according to a fourth embodiment; and

FIG. 16 is a circuit diagram illustrating an amplifier according to a fifth embodiment.

### DESCRIPTION OF EMBODIMENTS

Hereinafter, embodiments of the present disclosure will be specifically described with reference to the accompanying drawings. In the present specification and drawings, constituent elements or components having substantially the same functional configuration are designated by the same reference numerals, and a redundant description thereof may be omitted.

### First Embodiment

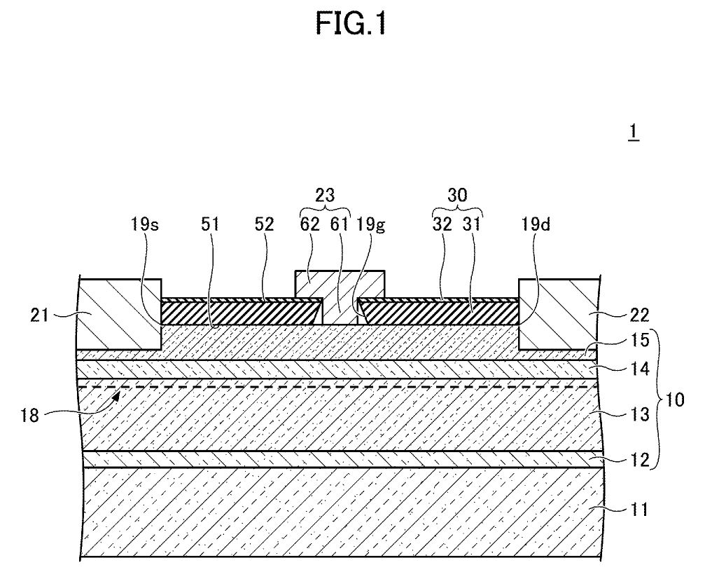

A first embodiment will be described. A first embodiment relates to a semiconductor device including a high electron mobility transistor (HEMT). FIG. 1 is a cross sectional view illustrating the semiconductor device according to the first embodiment.

As illustrated in FIG. 1, a semiconductor device 1 according to the first embodiment includes a substrate 11, and a semiconductor layer 10 provided above the substrate 11. The semiconductor layer 10 is a nitride semiconductor layer, for example. The semiconductor layer 10 includes a nucleation layer 12, a channel layer 13, a spacer layer 14, and a barrier layer 15. The nucleation layer 12 is provided on the substrate 11. The channel layer 13 is provided on the nucleation layer 12. The spacer layer 14 is provided on the channel layer 13. The barrier layer 15 is provided on the spacer layer 14.

The substrate 11 is a semi-insulating SiC substrate, for example. The nucleation layer 12 is a AlN layer having a thickness of 5 nm or greater and 150 nm or less, for example. The channel layer 13 is a GaN layer having a thickness of 50 nm or greater and 200 nm or less, for example. The spacer layer 14 is a AlGaN layer having a thickness of 0.5 nm or greater and 3 nm or less, for example. The barrier layer 15 is a AlGaN layer having a thickness of 20 nm or greater and 100 nm or less, for example. A two-dimensional electronic gas (2DEG) 18 is present near an upper surface of the channel layer 13.

The semiconductor device 1 has an amorphous insulating layer 30. The insulating layer 30 is provided on the barrier layer 15. A thickness of the insulating layer 30 is 20 nm or greater and 100 nm or less, and preferably 30 nm or greater and 50 nm or less. The insulating layer 30 includes silicon (Si) and nitrogen (N).

The insulating layer 30 includes a first region 31 and a second region 32. The first region 31 is in contact with the semiconductor layer 10. The first region 31 has a first surface 51 in contact with the semiconductor layer 10, and a second surface 52 opposite to the first surface 51. The second region 32 is provided on the first region 31. That is, the first region 31 is provided between the semiconductor layer 10 and the second region 32.

For example, a molar ratio of N atoms with respect to Si atoms in the first region 31 is 1.1 or higher and 1.33 or lower. The first region 31 may include oxygen at a concentration of 2 atomic% or higher and 4 atomic% or lower. For example, the first region 31 has a density of 2.50 g/cm³ or higher and a refraction index of 2.0 or higher and 2.1 or lower. In the first region 31, the density increases as a distance from the semiconductor layer 10 increases. Preferably, the density at the second surface 52 is higher than the density at the first surface 51 by 0.05 g/cm³ or more. For example, the density at the first surface 51 is 2.50 g/cm³ or higher and 2.60 g/cm³ or lower, and the density at the second surface 52 is 2.65 g/cm³ or higher and 2.75 g/cm³ or lower.

For example, a composition of the second region 32 can be represented by Si₃₋ₓN₄₋₂ₓOₓ, where x is 1.2 or greater and 1.8 or less. For example, a thickness of the second region 32 is 2 nm or greater and 5 nm or less, and a remainder of the insulating layer 30 corresponds to the first region 31.

A device isolation region defining a device region is formed in the semiconductor layer 10. In the device region, a recess 19s for a source and a recess 19d for a drain are formed in a laminate of the barrier layer 15 and the insulating layer 30. The recess 19s and the recess 19d penetrate the insulating layer 30. A bottom surface of the recess 19s and a bottom surface of the recess 19d are located in the barrier layer 15.

An opening 19g for a gate is formed in the insulating layer 30. The opening 19g penetrates the insulating layer 30 and reaches the semiconductor layer 10. The opening 19g is located between the recess 19s and the recess 19d in a plan view. A width of the opening 19g becomes smaller as the distance from the semiconductor layer 10 increases, at least in the first region 31. That is, a wall surface of the opening 19g is inclined from a plane perpendicular to an upper surface of the semiconductor layer 10, at least in the first region 31. The "width" in the present disclosure is a dimension in an axial direction that defines a gate length.

The semiconductor device 1 includes a source electrode 21, a drain electrode 22, and a gate electrode 23. The source electrode 21 is provided inside the recess 19s, and the drain electrode 22 is provided inside the recess 19d. The gate electrode 23 includes a first portion 61 inside the opening 19g, and a second portion 62 provided on the insulating layer 30. The first portion 61 and the second portion 62 are connected to each other.

The source electrode 21 and the drain electrode 22 include a tantalum (Ta) film having a thickness of 10 nm or greater and 50 nm or less and an aluminum (Al) film having a thickness of 100 nm or greater and 500 nm or less provided on the Ta film, for example. The source electrode 21 and the drain electrode 22 are in ohmic contact with the semiconductor layer 10. The gate electrode 23 includes a nickel (Ni) film having a thickness of 10 nm or greater and 50 nm or less and a gold (Au) film having a thickness of 300 nm or greater and 500 nm or less provided on the Au film, for example. The gate electrode 23 is in Schottky contact with the semiconductor layer 10.

A portion of the gate electrode 23 in contact with the semiconductor layer 10 is separated from the insulating layer 30. For example, the portion of the gate electrode 23 in contact with the insulating layer 30 is separated from the insulating layer 30 by a distance of 0.1 nm or greater and 50 nm or less.

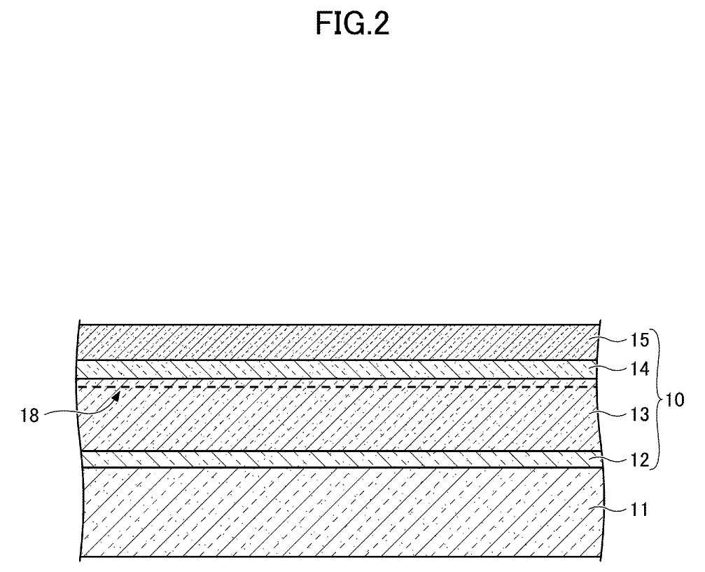

Next, a method for manufacturing the semiconductor device 1 according to the first embodiment will be described. FIG. 2 through FIG. 8 are cross sectional views illustrating the method for manufacturing the semiconductor device 1 according to the first embodiment.

First, as illustrated in FIG. 2, the semiconductor layer 10 is formed on the substrate 11. When forming the semiconductor layer 10, the nucleation layer 12, the channel layer 13, the spacer layer 14, and the barrier layer 15 are formed by metal organic vapor phase epitaxy (MOVPE), for example. When forming the semiconductor layer 10, a gas mixture of trimethylgallium (TMGa) gas as a gallium (Ga) source and ammonia (NH₃) gas as a nitrogen (N) source is used as a source gas to grow the GaN layer. When growing the AlN layer, a gas mixture of trimethylaluminum (TMAl) gas as a Al source and NH₃ gas as the N source is used as a source gas. When growing the AlGaN layer, a gas mixture of TMAl gas as the Al source, TMGa gas as the Ga source, and NH₃ gas as the N source is used as a source gas. Whether to supply or not to supply and the flow rates of the TMAl gas and the TMGa gas are appropriately set according to the composition of the semiconductor layer to be grown. Hydrogen (H₂) gas or nitrogen gas (N₂) is used as a carrier gas. For example, a growth pressure is set to in a range of approximately 1 kPa to approximately 100 kPa, and a growth temperature is set to in a range of approximately 700°C to approximately 1200°C.

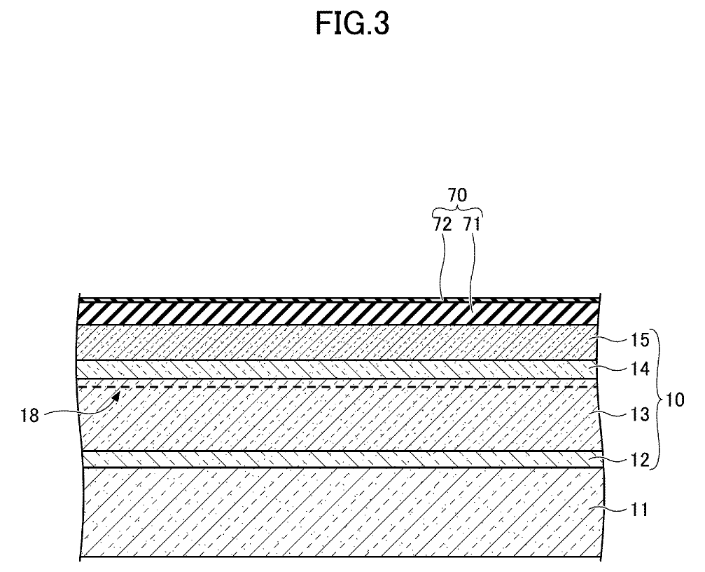

Next, as illustrated in FIG. 3, an amorphous layer 70 including Si and N is formed on the semiconductor layer 10 by plasma chemical vapor deposition (CVD). A gas mixture of silane (SiH₄) as a Si source and nitrogen gas (N₂) as the N source is used as a source gas. In this case, a flow rate of SiH₄ supplied into a chamber is set to 1.0 sccm or greater and 2.0 sccm or less, and a flow rate of N₂ is set to approximately 150 sccm, for example. The flow rate of the SiH₄ supplied into the chamber may be 1.0 sccm or greater and 1.8 sccm or less, or may be 1.0 sccm or greater and 1.6 sccm or less.

The amorphous layer 70 includes a first region 71 and a second region 72. The first region 71 is in contact with the semiconductor layer 10. The second region 72 is provided on the first region 71. In other words, the first region 71 is provided between the semiconductor layer 10 and the second region 72.

For example, a molar ratio of N atoms with respect to Si atoms in the first region 71 is 1.1 or higher and 1.33 or lower. The first region 71 may include oxygen at a concentration of 2 atomic% or higher and 4 atomic% or lower. For example, a composition of the second region 72 can be represented by Si₃₋ₓN₄₋₂ₓOₓ, where x is 1.2 or greater and 1.8 or less. For example, a thickness of the second region 72 is 2 nm or greater and 5 nm or less, and a remainder of the amorphous layer 70 corresponds to the first region 71.

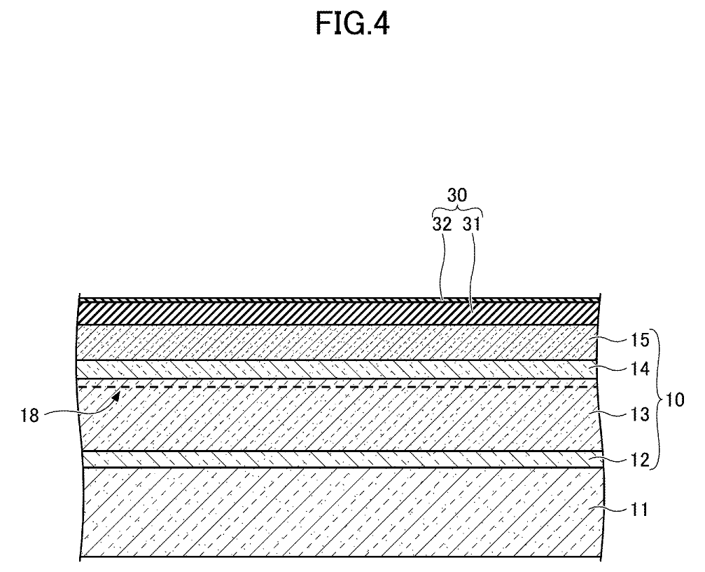

Thereafter, the amorphous layer 70 is annealed at a temperature of 600°C or higher. As a result, as illustrated in FIG. 4, the insulating layer 30 is formed from the amorphous layer 70. The insulating layer 30 that is formed in this manner includes the first region 31 and the second region 32, and a density of the first region 31 increases as the distance from the semiconductor layer 10 increases.

Subsequently, a device isolation region defining a device region is formed in the semiconductor layer 10. When forming the device isolation region, a photoresist pattern for exposing a region where the device isolation region is to be formed is formed on the semiconductor layer 10, and ion implantation of argon (Ar) or the like is performed using the pattern as a mask, for example. Dry etching using chlorine-based (Cl-based) gas may be performed using the pattern as an etching mask.

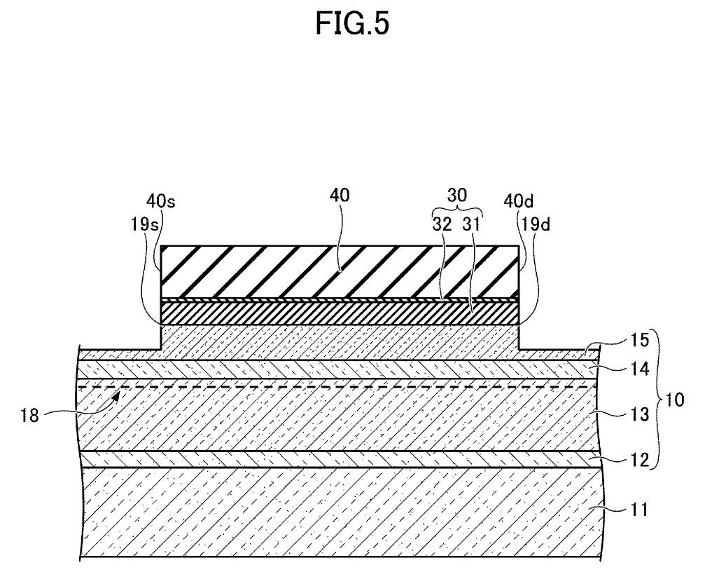

Next, as illustrated in FIG. 5, a surface protection film 40 is formed on the insulating layer 30. The surface protection film 40 includes a layer of an oxide, a nitride, or an oxynitride of Si, Al, Hf, Zr, Ti, Ta, or W, for example, and is preferably a Si oxide film. The surface protection film 40 can be formed by plasma CVD, for example. The surface protection film 40 may be formed by atomic layer deposition (ALD) or sputtering.

Thereafter, openings 40s and 40d are formed in the surface protection film 40, and recesses 19s and 19d are formed in the laminate of the barrier layer 15 and the insulating layer 30. When forming the openings 40s and 40d and the recesses 19s and 19d, a photoresist pattern for exposing regions where the recesses 19s and 19d are to be formed by photolithography, for example, is formed on the surface protection film 40. Further, dry etching is performed using fluorine-based gas or chlorine-based gas using the pattern as an etching mask. The recesses 19s and 19d are formed so that the bottom surfaces of the recesses 19s and 19d are located in the barrier layer 15.

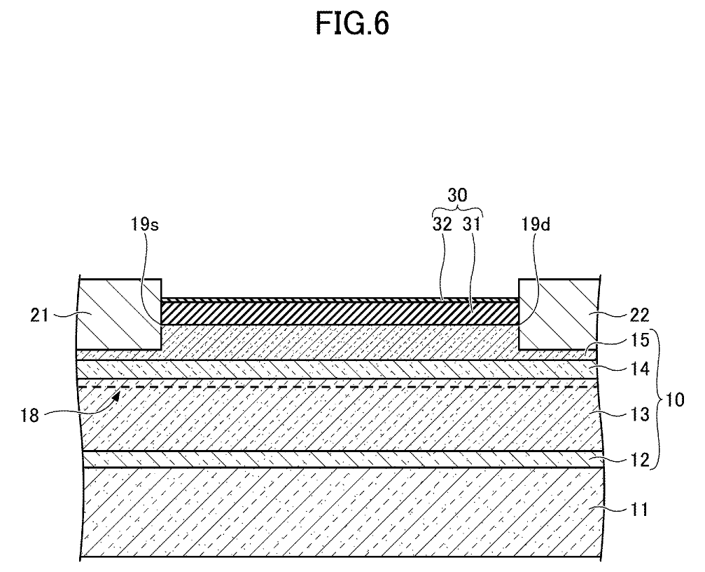

Next, as illustrated in FIG. 6, the source electrode 21 is formed inside the recess 19s, and the drain electrode 22 is formed inside the recess 19d. The source electrode 21 and the drain electrode 22 can be formed by a lift-off method, for example. That is, a photoresist pattern for exposing the regions where the source electrode 21 and the drain electrode 22 are to be formed is formed, a metal film is formed by vapor deposition using the pattern as a growth mask, and the pattern is removed together with the metal film thereon. When forming the metal film, a Ta film is formed, and an Al film is formed on the Ta film, for example. Next, a heat treatment is performed at a temperature in a range of 400°C to 1000°C (for example, at 550°C) in a nitrogen atmosphere, for example, to establish ohmic characteristics. After forming the source electrode 21 and the drain electrode 22, the surface protection film 40 is removed.

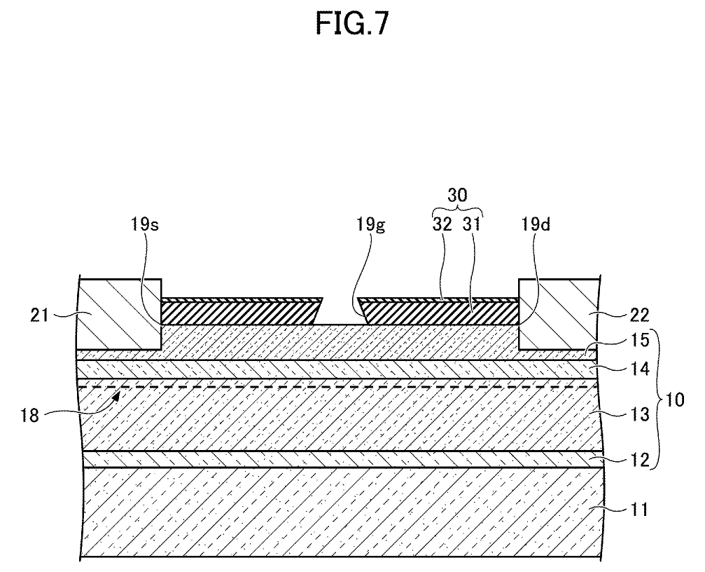

Thereafter, as illustrated in FIG. 7, an opening 19g is formed in the insulating layer 30. When forming the opening 19g, a photoresist pattern for exposing a region where the opening 19g is to be formed is formed on the insulating layer 30 by photolithography, for example, and dry etching using fluorine-based gas is performed using the pattern as an etching mask. In the first region 31 of the insulating layer 30, the density increases as the distance from the semiconductor layer 10 increases, and thus, side etching is more likely to occur in a portion closer to the semiconductor layer 10. Accordingly, the width of the opening 19g becomes smaller as the distance from the semiconductor layer 10 increases, at least in the first region 31.

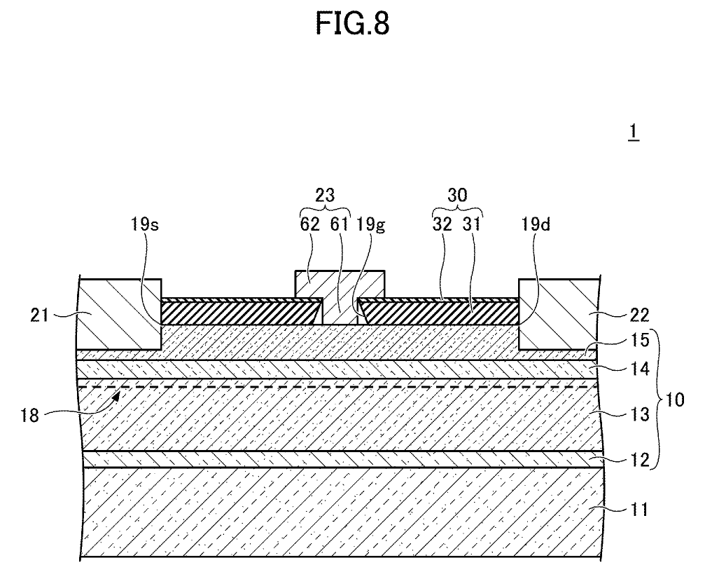

Next, as illustrated in FIG. 8, the gate electrode 23, having the first portion 61 inside the opening 19g and the second portion 62 provided on the insulating layer 30, is formed. The gate electrode 23 can be formed by a lift-off method, for example. That is, a photoresist pattern for exposing a region where the gate electrode 23 is to be formed is formed, a metal film is formed by vapor deposition using the pattern as a growth mask, and the pattern is removed together with the metal film thereon. When forming the metal film, a Ni film is formed, and an Au film is formed on the Ni film, for example. Because the width of the opening 19g becomes smaller as the distance from the insulating layer 30 increases, at least in the first region 31, a portion of the gate electrode 23 in contact with the semiconductor layer 10 is separated from the insulating layer 30. After forming the gate electrode 23, post-annealing of the gate electrode 23 is performed.

The semiconductor device 1 according to the first embodiment can be manufactured in the manner described above.

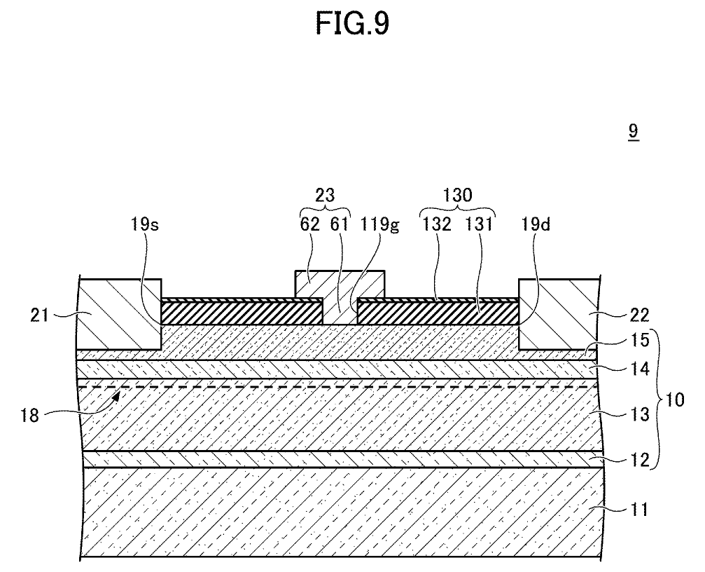

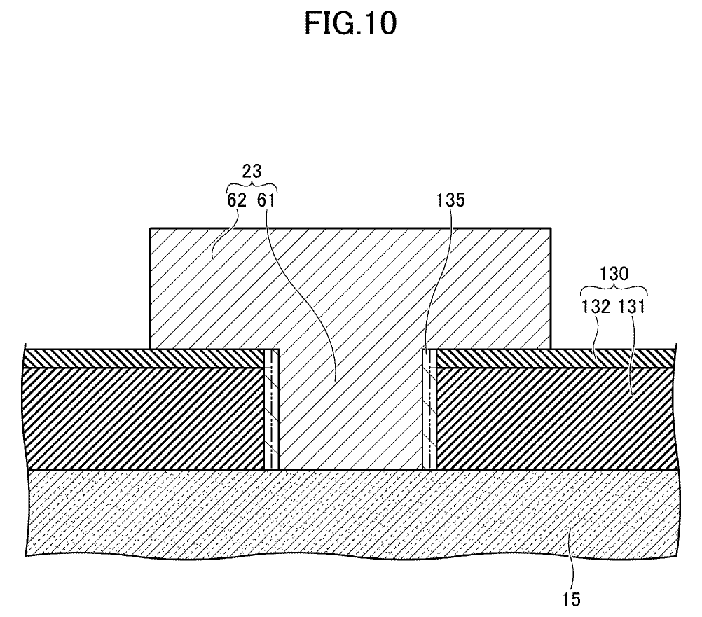

Next, a reference example will be described. A semiconductor device according to the reference example differs from the semiconductor device 1 according to the embodiment mainly in the configuration of the insulating layer. FIG. 9 is a cross sectional view illustrating the semiconductor device according to the reference example. FIG. 10 is a cross sectional view illustrating an insulating layer and a gate electrode in the reference example.

As illustrated in FIG. 9, a semiconductor device 9 according to the reference example includes an amorphous insulating layer 130 in place of the insulating layer 30. The insulating layer 130 includes a first region 131 and a second region 132. The first region 131 is in contact with the semiconductor layer 10. The second region 132 is provided above the first region 131. That is, the first region 131 is provided between the semiconductor layer 10 and the second region 132.

A molar ratio of N atoms with respect to Si atoms in the first region 131 is 1.1 or greater and 1.33 or less. The first region 131 may include oxygen at a concentration of 2 atomic% or higher and 4 atomic% or lower. The first region 131 has a density of 2.50 g/cm³ or higher. The density of the first region 131 is substantially uniform. A composition of the second region 132 can be represented by Si₃₋ₓN₄₋₂ₓOₓ, where x is 1.2 or greater and 1.8 or less. A thickness of the second region 132 is 2 nm or greater and 5 nm or less, and a remaining portion of the insulating layer 130 corresponds to the first region 131.

When forming the insulating layer 130, an amorphous layer is formed by plasma CVD, and the amorphous layer is thereafter annealed. When forming the amorphous layer, a flow rate of SiH₄ supplied into the chamber is set to approximately 2.2 sccm, and a flow rate of N₂ is set to approximately 150 sccm. An annealing temperature of the amorphous layer is approximately 350°C. The insulating layer 130 that is formed in this manner has a substantially uniform density in the first region 131.

An opening 119g for a gate is formed in the insulating layer 130. The opening 119g penetrates the insulating layer 130 and reaches the semiconductor layer 10. The opening 119g is located between the recess 19s and the recess 19d in the plan view. A width of the opening 119g is substantially constant in the first region 131. That is, a wall surface of the opening 119g is substantially perpendicular to the upper surface of the semiconductor layer 10 in the first region 131. The opening 119g is formed in the same manner as the opening 19g, but because the first region 131 has a substantially uniform density, the opening 119g has a substantially constant width in the first region 131.

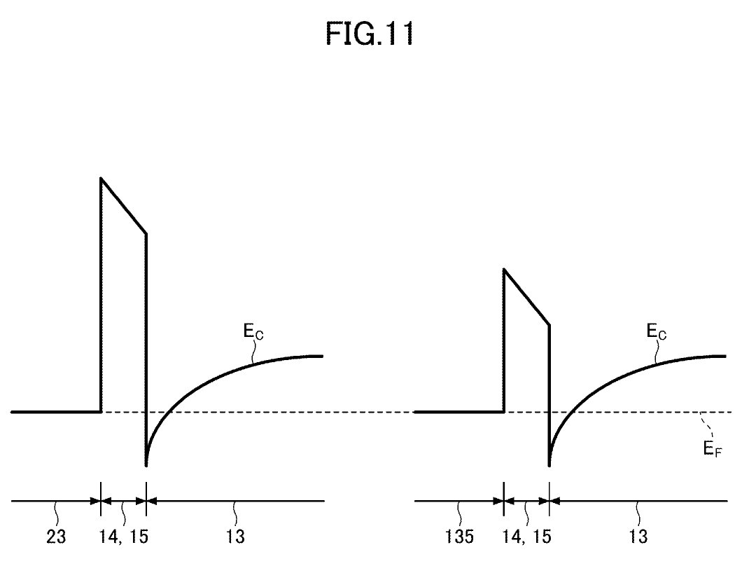

The gate electrode 23 includes a first portion 61 inside the opening 119g, and a second portion 62 provided on the insulating layer 130. The first portion 61 and the second portion 62 are connected to each other. The gate electrode 23 is formed by the same method as that of the first embodiment, and the entire first portion 61 is in contact with the insulating layer 130 before the post-annealing. Further, when the post-annealing is performed, Ni included in the gate electrode 23 and Si included in the insulating layer 130 react with each other, and an alloy layer 135 including Ni and Si is formed, as illustrated in FIG. 10. As illustrated in FIG. 11, the Schottky barrier is smaller in a portion where the alloy layer 135 is in Schottky contact with the semiconductor layer 10 than in a portion where the gate electrode 23 is in Schottky contact with the semiconductor layer 10. As a result, a leakage current flows more easily in the portion where the alloy layer 135 is in Schottky contact with the semiconductor layer 10 than in the portion where the gate electrode 23 is in Schottky contact with the semiconductor layer 10. FIG. 11 is a diagram illustrating band structures in the portion where the gate electrode 23 is in Schottky contact with the semiconductor layer 10 and the portion where the alloy layer 135 is in Schottky contact with the semiconductor layer 10. In FIG. 11, a solid line indicates the conduction band minimum E_{C}, and a broken line indicates the Fermi level E_{F}.

In contrast, in the semiconductor device 1 according to the first embodiment, because the density in the first region 31 of the insulating layer 30 becomes higher as the distance from the semiconductor layer 10 increases, the width of the opening 19g becomes smaller as the distance from the insulator layer 10 increases, at least in the first region 31. Further, the portion of the gate electrode 23 in contact with the semiconductor layer 10 is separated from the insulating layer 30. Accordingly, even when the post-annealing is performed on the gate electrode 23, an alloy layer in Schottky contact with the semiconductor layer 10 is less likely to be formed. For this reason, the generation of the leakage current caused by the presence of the alloy layer can be reduced.

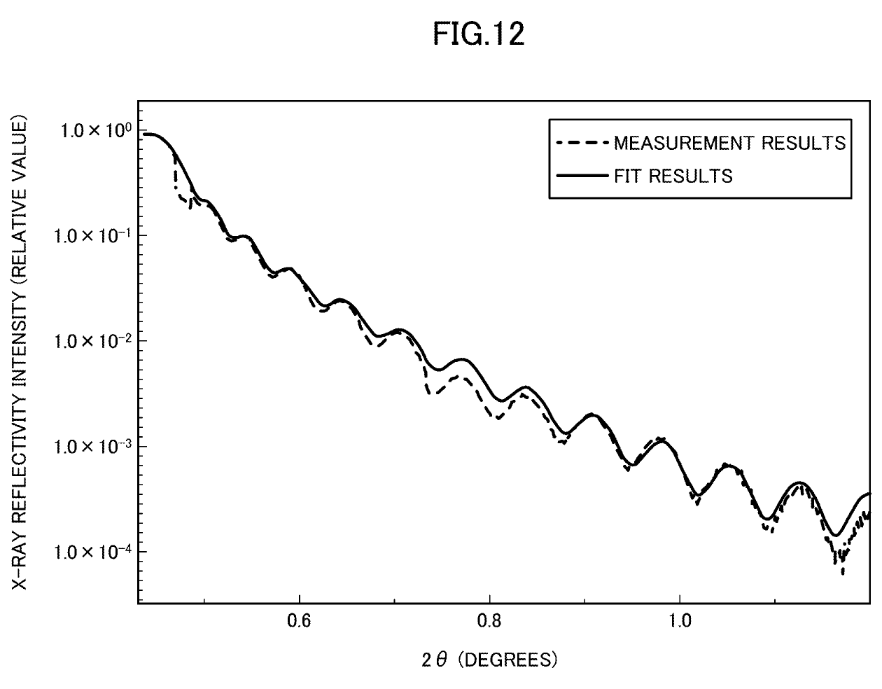

Next, results of measurement of an insulating layer that has a thickness of 100 nm and is formed on a semiconductor layer, performed by the present inventors using an X-ray reflectivity (XRR) method will be described. When forming the insulating layer, an amorphous layer was formed by plasma CVD with a RF power set to 60W, a flow rate of SiH₄ supplied into the chamber set to 1.6 sccm, and a flow rate of N₂ set to 150 sccm, and the amorphous layer was thereafter annealed at 700°C. FIG. 12 is a diagram illustrating the results of measurement using the XRR method. In FIG. 12, the ordinate indicates an X-ray reflectivity intensity (relative value), and the abscissa indicates 2θ (degrees).

Fit results in FIG. 12 show fit results of measurement results that are actually obtained. When the density was computed from the fit results, the density at a first surface (lower surface) of the insulating layer was 2.53 g/cm³, and the density at a second surface (upper surface) of the insulating layer was 2.61 g/cm³.

The density of the insulating layer included in the semiconductor device can also be measured from a scanning transmission electron microscope (STEM) image obtained using a scanning electron microscope (SEM) with a low acceleration voltage, for example.

### Second Embodiment

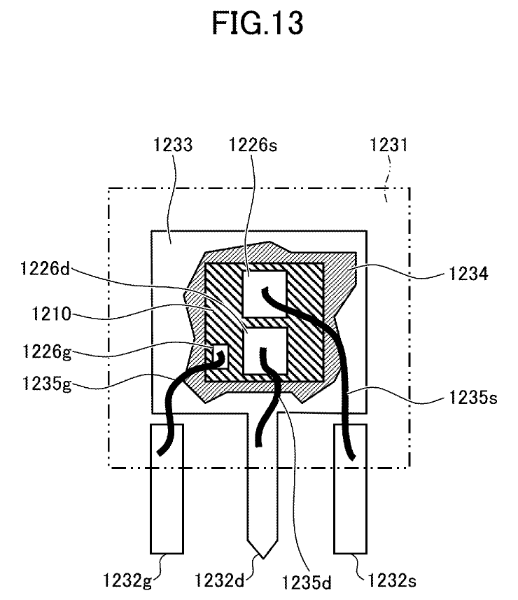

Next, a second embodiment will be described. The second embodiment relates to a discrete package of a HEMT. FIG. 13 is a diagram illustrating the discrete package according to the second embodiment.

In the second embodiment, a back surface of a semiconductor device 1210 having the same structure as that of the first embodiment is fixed to a land (die pad) 1233 using a die attach agent 1234, such as solder or the like, as illustrated in FIG. 13. One end of a wire 1235d, such as a Al wire or the like, is connected to a drain pad 1226d connected to the drain electrode 22, and the other end of the wire 1235d is connected to a drain lead 1232d integrated with the land 1233. One end of a wire 1235s, such as a Al wire or the like, is connected to a source pad 1226s connected to the source electrode 21, and the other end of the wire 1235s is connected to a source lead 1232s independent of the land 1233. One end of a wire 1235g, such as a Al wire or the like, is connected to a gate pad 1226g connected to the gate electrode 23, and the other end of the wire 1235g is connected to a gate lead 1232g independent of the land 1233. The land 1233, the semiconductor device 1210, or the like are packaged by a mold resin 1231 so that a portion of the gate lead 1232g, a portion of the drain lead 1232d, and a portion of the source lead 1232s protrude from the package.

Such a discrete package can be manufactured in the following manner, for example. First, the semiconductor device 1210 is fixed to the land 1233 of a lead frame using the die attach agent 1234, such as solder or the like. Next, by bonding the wires 1235g, 1235d, and 1235s, the gate pad 1226g is connected to the gate lead 1232g of the lead frame, the drain pad 1226d is connected to the drain lead 1232d of the lead frame, and the source pad 1226s is connected to the source lead 1232s of the lead frame. Thereafter, encapsulation using the mold resin 1231 is performed by transfer molding. Subsequently, the lead frame is removed.

### Third Embodiment

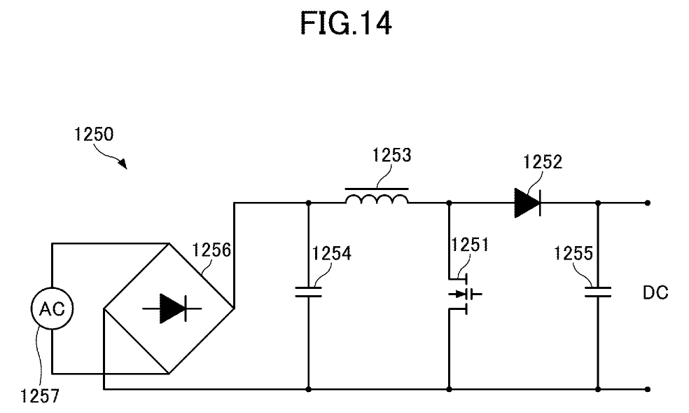

Next, a third embodiment will be described. The third embodiment relates to a power factor correction (PFC) circuit including a HEMT. FIG. 14 is a circuit diagram illustrating the PFC circuit according to the third embodiment.

A PFC circuit 1250 includes a switching element (transistor) 1251, a diode 1252, a choke coil 1253, capacitors 1254 and 1255, a diode bridge 1256, and an alternating current (AC) power supply 1257. A drain electrode of the switching element 1251, an anode terminal of the diode 1252, and one terminal of the choke coil 1253 are connected. A source electrode of the switching element 1251, one terminal of the capacitor 1254, and one terminal of the capacitor 1255 are connected. The other terminal of the capacitor 1254 and the other terminal of the choke coil 1253 are connected. The other terminal of the capacitor 1255 and a cathode terminal of the diode 1252 are connected. In addition, a gate driver is connected to a gate electrode of the switching element 1251. The AC power supply 1257 is connected between both terminals of the capacitor 1254 via the diode bridge 1256. A DC power supply is connected between both terminals of the capacitor 1255. In the present embodiment, a semiconductor device having the same structure as that of the first embodiment is used for the switching element 1251.

When manufacturing the PFC circuit 1250, the switching element 1251 is connected to the diode 1252, the choke coil 1253, or the like using solder or the like, for example.

### Fourth Embodiment

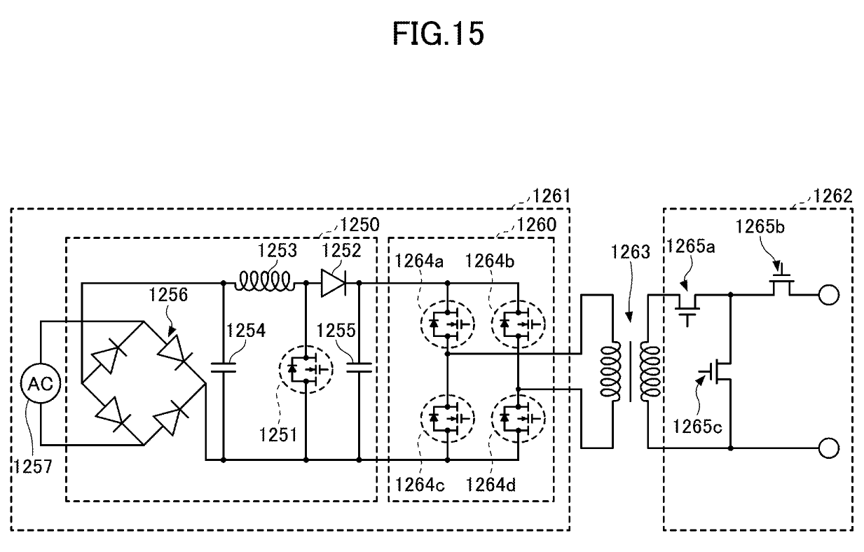

Next, a fourth embodiment will be described. The fourth embodiment relates to a power supply including a HEMT, which is suitable for use as a server power supply. FIG. 15 is a circuit diagram illustrating the power supply according to the fourth embodiment.

The power supply includes a high-voltage primary circuit 1261, a low-voltage secondary circuit 1262, and a transformer 1263 disposed between the primary circuit 1261 and the secondary circuit 1262.

The primary circuit 1261 includes the PFC circuit 1250 according to the third embodiment, and an inverter circuit, such as a full-bridge inverter circuit 1260, for example, that is connected between both terminals of the capacitor 1255 of the PFC circuit 1250. The full-bridge inverter circuit 1260 includes a plurality of (four in this example) switching elements 1264a, 1264b, 1264c and 1264d.

The secondary circuit 1262 includes a plurality of (three in this example) switching elements 1265a, 1265b, and 1265c.

In the present embodiment, the switching element 1251 of the PFC circuit 1250 and the switching elements 1264a, 1264b, 1264c, and 1264d of the full-bridge inverter circuit 1260, which constitute the primary circuit 1261, have the same structure as that of the first embodiment. On the other hand, a general metal-insulator-semiconductor field effect transistor (MISFET) is used for the switching elements 1265a, 1265b, and 1265c of the secondary circuit 1262.

### Fifth Embodiment

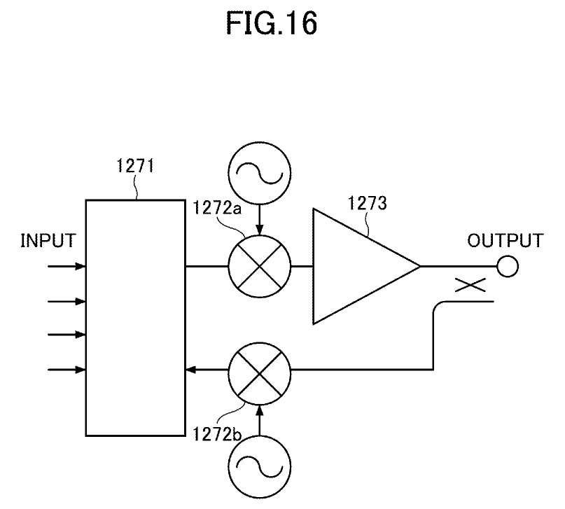

Next, a fifth embodiment will be described. The fifth embodiment relates to an amplifier including a HEMT. FIG. 16 is a circuit diagram illustrating the amplifier according to the fifth embodiment.

As illustrated in FIG. 16, the amplifier includes a digital predistortion circuit 1271, mixers 1272a and 1272b, and a power amplifier 1273.

The digital predistortion circuit 1271 compensates for nonlinear distortions of an input signal. The mixer 1272a mixes the input signal compensated of the nonlinear distortions and a AC signal. The power amplifier 1273 includes a semiconductor device having the same structure as that of the first embodiment, and amplifies the input signal mixed with the AC signal. In the present embodiment, by switching a switch, for example, an output-side signal can be mixed with the AC signal in the mixer 1272b and sent to the digital predistortion circuit 1271. The amplifier can be used as a high-frequency amplifier or a high-power amplifier.

The high-frequency amplifier can be used in a transmission and reception device for a mobile phone base station, a radar device, and a microwave generation device.

According to the disclosed technique, it is possible to reduce a leakage current.

Various aspects of the subject-matter described herein may be set out non-exhaustively in the following numbered clauses:

### Clause 1

A semiconductor device comprising:
a semiconductor layer;
an amorphous insulating layer, provided on the semiconductor layer, including silicon and nitrogen, and having an opening reaching the semiconductor layer; and
a gate electrode having a portion inside the opening and in Schottky contact with the semiconductor layer,
wherein the insulating layer includes a first region having a density that becomes higher as a distance from the semiconductor layer increases.

### Clause 2

The semiconductor device according to clause 1, wherein the first region is in contact with the semiconductor layer.

### Clause 3

The semiconductor device according to clause 2, wherein:
the first region includes:
   a first surface in contact with the semiconductor layer; and
   a second surface opposite the first surface, and a density at the second surface is higher than a density at the first surface by 0.05 g/cm³ or more.

### Clause 4

The semiconductor device according to any one of clauses 1 to 3, wherein a molar ratio of nitrogen atoms with respect to silicon atoms in the first region is 1.1 or higher and 1.33 or lower.

### Clause 5

The semiconductor device according to any one of clauses 1 to 4, wherein the insulating layer includes oxygen.

### Clause 6

The semiconductor device according to clause 5, wherein the first region includes oxygen at a concentration of 2 atomic% or higher and 4 atomic% or lower.

### Clause 7

The semiconductor device according to clause 5 or 6, wherein the insulating layer includes a second region that is provided on the first region and has a composition represented by Si₃₋ₓN₄₋₂ₓOₓ, where x is 1.2 or greater and 1.8 or less.

### Clause 8

The semiconductor device according to clause 7, wherein a thickness of the second region is 2 nm or greater and 5 nm or less.

### Clause 9

The semiconductor device according to any one of clauses 1 to 8, wherein the first region has a density of 2.50 g/cm³ or higher.

### Clause 10

The semiconductor device according to any one of clauses 1 to 9, wherein a portion of the gate electrode in contact with the semiconductor layer is separated from the insulating layer.

### Clause 11

The semiconductor device according to clause 10, wherein the portion of the gate electrode in contact with the semiconductor layer is separated from the insulating layer by a distance of 0.1 nm or greater and 50 nm or less.

### Clause 12

The semiconductor device according to clause 10 or 11, wherein a width of the opening becomes smaller as a distance from the semiconductor layer increases at least in the first region.

### Clause 13

The semiconductor device according to any one of clauses 1 to 12, wherein the gate electrode includes nickel.

### Clause 14

A method for manufacturing a semiconductor device, comprising:
forming an amorphous insulating layer including silicon and nitrogen on a semiconductor layer by a plasma chemical vapor deposition;
forming an opening in the insulating layer so that the opening reaches the semiconductor layer; and
forming a gate electrode, having a portion inside the opening, and in Schottky contact with the semiconductor layer;
wherein the insulating layer includes a first region having a density that becomes higher as a distance from the semiconductor layer increases.

### Clause 15

The method for manufacturing the semiconductor device according to clause 14, wherein:
the forming the amorphous insulating layer includes:
   forming an amorphous layer including silicon and nitrogen by supplying silane and ammonia into a chamber; and
   annealing the amorphous layer at a temperature of 600°C or higher, and
   a flow rate of silane supplied into the chamber is 1.0 sccm or greater and 2.0 sccm or less.

Although the embodiments are numbered with, for example, “first,” “second,” “third,” “fourth,” or “fifth, "the ordinal numbers do not imply priorities of the embodiments. Many other variations and modifications will be apparent to those skilled in the art.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A semiconductor device comprising:
a semiconductor layer;
an amorphous insulating layer, provided on the semiconductor layer, including silicon and nitrogen, and having an opening reaching the semiconductor layer; and
a gate electrode having a portion inside the opening and in Schottky contact with the semiconductor layer,
wherein the insulating layer includes a first region having a density that becomes higher as a distance from the semiconductor layer increases.

2. The semiconductor device as claimed in claim 1, wherein the first region is in contact with the semiconductor layer.

3. The semiconductor device as claimed in claim 2, wherein:
the first region includes:
a first surface in contact with the semiconductor layer; and
a second surface opposite the first surface, and
a density at the second surface is higher than a density at the first surface by 0.05 g/cm³ or more.

4. The semiconductor device as claimed in claim 1, wherein a molar ratio of nitrogen atoms with respect to silicon atoms in the first region is 1.1 or higher and 1.33 or lower.

5. The semiconductor device as claimed in claim 1, wherein the insulating layer includes oxygen.

6. The semiconductor device as claimed in claim 5, wherein the first region includes oxygen at a concentration of 2 atomic% or higher and 4 atomic% or lower.

7. The semiconductor device as claimed in claim 5, wherein the insulating layer includes a second region that is provided on the first region and has a composition represented by Si₃₋ₓN₄₋₂ₓOₓ where x is 1.2 or greater and 1.8 or less.

8. The semiconductor device as claimed in claim 7, wherein a thickness of the second region is 2 nm or greater and 5 nm or less.

9. The semiconductor device as claimed in claim 1, wherein the first region has a density of 2.50 g/cm³ or higher.

10. The semiconductor device as claimed in claim 1, wherein a portion of the gate electrode in contact with the semiconductor layer is separated from the insulating layer.

11. The semiconductor device as claimed in claim 10, wherein the portion of the gate electrode in contact with the semiconductor layer is separated from the insulating layer by a distance of 0.1 nm or greater and 50 nm or less.

12. The semiconductor device as claimed in claim 10, wherein a width of the opening becomes smaller as a distance from the semiconductor layer increases at least in the first region.

13. The semiconductor device as claimed in claim 1, wherein the gate electrode includes nickel.

14. A method for manufacturing a semiconductor device, comprising:
forming an amorphous insulating layer including silicon and nitrogen on a semiconductor layer by a plasma chemical vapor deposition;
forming an opening in the insulating layer so that the opening reaches the semiconductor layer; and
forming a gate electrode, having a portion inside the opening, and in Schottky contact with the semiconductor layer;
wherein the insulating layer includes a first region having a density that becomes higher as a distance from the semiconductor layer increases.

15. The method for manufacturing the semiconductor device as claimed in claim 14, wherein:
the forming the amorphous insulating layer includes:
forming an amorphous layer including silicon and nitrogen by supplying silane and ammonia into a chamber; and
annealing the amorphous layer at a temperature of 600°C or higher, and
a flow rate of silane supplied into the chamber is 1.0 sccm or greater and 2.0 sccm or less.
